(19) United States
(12) Patent Application Publication
(10) Pub. No.: US 2006/0017132 A1
(43) Pub. Date: Jan. 26, 2006

(54) Method for producing a dielectric and semiconductor structure

(75) Inventors: Albert Birner, Dresden (DE); Andreas Weber, Dresden (DE); Till Schloesser, Dresden (DE); Joern Luetzen, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munich (DE)

(21) Appl. No.: 11/167,946

(22) Filed: Jun. 28, 2005

(30) Foreign Application Priority Data
Jun. 29, 2004 (DE) 10 2004 031 453.5

(51) Int. Cl. H01L 29/00

(52) U.S. Cl. 257/510

(57) ABSTRACT

The present invention relates to a method for producing a dielectric on a semiconductor body having the following steps that are to be performed successively: provision of a semiconductor body, application of a dielectric layer on at least parts of a first surface of the semiconductor body in such a way as at least partly to form an interface between the dielectric layer and the semiconductor body, and thermal annealing of the semiconductor body and the dielectric layer. The method according to the invention is distinguished by the fact that temporally prior to the annealing, for the purpose of improving the saturation and the electrical properties, fluorine-containing particles are introduced into regions of the semiconductor body and/or of the dielectric layer which adjoin the interface. The present invention furthermore relates to a corresponding semiconductor structure.

### CLAIM FOR PRIORITY

This application claims the benefit of priority to German Application No. 10 2004 031 453.5, filed Jun. 29, 2004, the contents of which are hereby incorporated by reference.

### TECHNICAL FIELD OF THE INVENTION

The present invention relates to a method for producing a dielectric on a semiconductor body and to a corresponding semiconductor structure.

### BACKGROUND OF THE INVENTION

Although applicable in principle to arbitrary integrated circuits, the present invention and also the problem area on which it is based will be explained with regard to integrated memory circuits in silicon technology, and in particular in STI technology.

In the context of increasing miniaturization in the field of microelectronics with the aim of fabricating extremely small electronic components having the highest possible reliability and service life, integrated circuits play a predominant part. Such integrated circuits typically have a multiplicity of field-effect-controlled components and capacitive elements. In the case of components of this type, the dielectrics form essential constituent parts of the component that have a considerable influence on the service life of the integrated circuit and thus of the entire semiconductor chip. The reliability of such a dielectric in turn is essentially characterized by its defect density.

Since the requirements made of, for example, the field-effect-controlled components mentioned in the introduction are being set ever higher, it is necessary to produce very high-quality gate oxides. In the case of a silicon dioxide, these are therefore preferably produced by means of a thermal oxidation of a silicon substrate.

For the quality of a dielectric on a semiconductor body, the interface between dielectric and semiconductor body, in particular, plays a very significant part since the service life of a field-effect-controlled semiconductor component essentially depends on the purity of the dielectric and also on the interface between dielectric and semiconductor body. A high defect density in the dielectric and at the interface results in a higher probability of an electrical breakdown after a certain period of time.

However, this interface between dielectric and semiconductor body has a finite density of interface states. These interface states, which are also referred to as “traps” or charge carrier traps, are undesirable and are to be avoided as far as possible. This is due to the fact that the interface states between dielectric and semiconductor body are undefined and may thus lead to undefined leakage currents along the interface. Moreover, in the case of gate oxides, the interface states have to be subjected to charge reversal in the event of each switching state, thereby giving rise to unfavorable transistor characteristic curves. In particular, this would lead to flatter current/voltage characteristic curves.

The interface states are caused by fixed charges, on the one hand, and by unsaturated bonds, on the other hand. These unsaturated bonds may have been produced for example by physical damage to the semiconductor body, such as, for example, by undesirable radiation or the like.

The interface states may also be generated by process bias influences during the process of manufacturing the semiconductor device.

Finally, the interface states may also arise as a result of process-induced impurities. Such impurities may arise during the fabrication process, in which the semiconductor body is subjected to a multiplicity of process steps, through incorporation of physical and chemical contaminations in the semiconductor body.

In order to largely eliminate such undefined interface states or at least to minimize them, a number of measures are known:

In accordance with a first method, it is possible to minimize the interface states in the process implementation by using a so-called sacrificial oxide process. In such a sacrificial oxide process, prior to the actual oxidation process, a thin silicon dioxide, typically a few nanometers thick, is produced on the semiconductor body, and is subsequently removed again. In this way, although the semiconductor body is thinned somewhat, this has the effect of, as it were, concomitantly removing undesirable interface states on the surface of the semiconductor body. However, it is problematic that initially performing a sacrificial oxide process cannot be effected in all fabrication processes for producing a dielectric. Particularly when producing so-called shallow trench semiconductor components, in which the dielectric is applied to the walls of a narrow trench, this is not practicable since the lateral structures would be significantly altered by the sacrificial oxide process. This is not desired in the case of such semiconductor components, however, in which structures having a defined structure width are to be produced.

In a further problem, not all impurities and thus undesirable interface states can be eliminated even with the use of such a sacrificial oxide process. Since very many impurities have a very high diffusion constant, these impurities, during the oxidation, are virtually driven in the semiconductor body directly in front of the sacrificial oxide produced and thus cannot be removed by the sacrificial oxide process. After the oxidation, the impurities diffuse very rapidly to the interface again and thus form the undesirable interface states. Therefore, the sole use of a sacrificial oxide process generally does not suffice to reduce the density of the undesirable interface states to an acceptable extent.

A second method, which is generally used in CMOS technologies, uses a so-called forming gas annealing process. During this forming gas annealing, the density of the traps is likewise minimized by a suitable choice of the annealing parameters. In this case, the traps are saturated by the hydrogen atoms contained in the forming gas, so that overall the density of the traps is minimized. The advantage when using hydrogen in the reduction of interface states consists in the fact that hydrogen does not adversely electrically influence the function of the semiconductor component. Forming gas annealing nowadays represents the best method for the saturation of traps.

What is problematic about this, however, is that the saturation of said traps may be lost again during subsequent thermal process steps, so that undesirable interface states may thus arise again. This is due to the fact that hydrogen has a relatively low bond energy in the region of 1 eV. At relatively high temperatures, these bonds are very easily broken again on account of the low bond energy of hydrogen.

Since, after the oxidation, the corresponding semiconductor component is typically subjected to at least one subsequent thermal process step and the interface states are thereby lost again in the case of forming gas annealing, this forming gas annealing for the saturation of the traps is improvable; in particular, this applies to the production of high-quality dielectrics. In particular, only a temporary reduction of the trap density is obtained here, but not a permanent reduction of the density of the interface states, that is to say a reduction acting over the entire service life of the semiconductor component. Forming gas annealing thus has the problem of degradation.

### SUMMARY OF THE INVENTION

The present invention reduces the density of undefined interface states as far as possible in the production of a dielectric on a semiconductor body.

The present invention relates to a method for producing a dielectric on a semiconductor body having the following to be performed successively: provision of a semiconductor body, application of a dielectric layer on at least parts of a first surface of the semiconductor body in such a way as at least partly to form an interface between the dielectric layer and the semiconductor body, and thermal annealing of the semiconductor body and the dielectric layer. The present invention furthermore relates to a corresponding semiconductor structure.

Accordingly, there are several embodiments in the invention, a few of which are listed below:

A method of the generic type for producing a dielectric on a semiconductor body, wherein, temporally prior to the annealing, for the purpose of improving the saturation and the electrical properties, fluorine-containing particles are introduced into regions of the semiconductor body and/or of the dielectric layer which adjoin the interface.

A semiconductor arrangement produced according to the invention, having a semiconductor body and having a dielectric layer applied on the first surface of the semiconductor body, fluorine-containing particles being arranged at an interface between the semiconductor body and the dielectric layer for the purpose of improving the saturation and the electrical properties of the interface.

In one aspect of the present invention, fluorine is incorporated in a defined manner at the interface between the semiconductor and the dielectric. This idea is based on the insight that fluorine, in comparison with hydrogen, is a very much more suitable element for a saturation process during a thermal annealing process. This is due to the fact that fluorine, with a bond energy of 5 eV, has a very much higher bonding energy than hydrogen (bond energy 1 eV).

By means of the targeted incorporation of fluorine as far as possible directly at the interfaces between dielectric and semiconductor, it is thus possible to obtain a saturation of said interfaces and thus a reduction of the state density thereof. Moreover, since fluorine exhibits a completely unproblematic electrical behavior in the semiconductor body and in the dielectric, this also improves the electrical parameters during a subsequent annealing process.

One particular advantage of using fluorine-containing particles during an annealing process consists in the fact that the saturation is improved thereby and a reduction of the trap density, in particular at the interface between the semiconductor body and the dielectric, is obtained on account of the improvement in the saturation.

As a result of the reduction of the defects in the region of the interface and in the dielectric, the probability of an electrical breakdown can be greatly reduced and, consequently, the service life of an individual semiconductor component can be significantly increased.

In another aspect, the dielectric layer is formed as silicon dioxide (SiO₂). As an alternative, the dielectric layer may also be formed as silicon nitride (Si₃N₄). It goes without saying that any other dielectric layer which adjoins the substrate of a semiconductor body would be conceivable. In addition or as an alternative, the dielectric layer may also contain high-K and/or low-K.

In an advantageous aspect of the invention, the dielectric layer is produced by means of a thermal oxidation. Thermally oxidized silicon, in particular, has a very much higher quality than silicon dioxide produced by deposition or by spinning-on and is preferably employed particularly in the case of high-quality dielectrics, such as, for example, in the case of a capacitor dielectric or a gate oxide, in the case of which the quality of the dielectric must naturally be particularly high. In addition or as an alternative, the dielectric layer may also be produced by LP-CVD (LPCVD=low pressure CVD) and/or by ALD-CVD (ALD-CVD atomic layer deposition CVD).

In a typical refinement, the semiconductor body is formed as a silicon substrate. In particular, the silicon substrate is provided as monocrystalline silicon in this case, although the invention can also be used, of course, in the case of polycrystalline silicon. Moreover, the invention is also suitable in the case of other, preferably silicon-containing semiconductor substrates, such as, for example, silicon-germanium or silicon carbide (SiC).

In a particularly advantageous aspect, the fluorine-containing particles are introduced by ion implantation of fluorine ions or ionized fluorine-containing molecules into the semiconductor body. By means of implantation, it is possible to set the depths and thus the range of the fluorine-containing particles in the dielectric layer or in the semiconductor body in a targeted manner. In this way, it is possible to ensure more or less precisely that the fluorine-containing particles are arranged as near as possible to the interface between semiconductor body and dielectric layer after the implantation. As a result of the thermal step following the implantation, the fluorine-containing particles or the fluorine ions can additionally be added very near to the interface or directly to the interface, whereby the saturation effect according to the invention is even greater.

A high-temperature implantation is particularly advantageous in this connection since the implanted fluorine ions are thereby already exposed to the desired temperature during the implantation and can thereby as it were diffuse to the interface to an extent by radiation-assisted diffusion. A subsequent thermal step can advantageously be dispensed with here.

In another advantageous aspect, a multiple implantation of the fluorine-containing particles at different doses and energies is performed during the implantation. In this way, it is possible to set a desired profile of the fluorine-containing particles in the semiconductor body or in the dielectric in a targeted manner.

The method according to the invention is preferably suitable in the case of such semiconductor structures having at least one trench introduced in the semiconductor body, in which, in the region of the trench or trenches, a more or less thin dielectric layer is applied to the trench walls and/or the trench bottom and/or for filling the trench. In the case of so-called STI technology, at the first surface of the semiconductor body, at least one trench is introduced into the semiconductor body and is subsequently filled with silicon oxide. It would also be conceivable for the dielectric layer to be applied only to the trench walls but not to the trench bottom. It would furthermore be conceivable for the dielectric layer to be applied to one side of the trench walls or to a plurality but not all of the sides of the trench walls. In addition or as an alternative, it may also be provided that this dielectric layer slightly overlaps the first surface from the trench.

In an advantageous embodiment of the method according to the invention, the fluorine-containing particles, in the case of structures of this type, are introduced by means of a so-called shallow trench implantation into the semiconductor body or the interface between semiconductor body and dielectric layer. The abovementioned multiple implantation is particularly advantageously suitable in particular in the case of semiconductor components which have very deep and/or very narrow trench structures, for example, such as the abovementioned STI semiconductor components.

The introduction of the fluorine-containing particles by ion implantation is typically introduced into the dielectric layer and/or into the semiconductor body after the application of the dielectric layer. In addition or as an alternative, however, it may also be provided that the fluorine-containing particles are introduced into the dielectric layer or into the corresponding semiconductor body prior to the application of said dielectric layer or during the application of the dielectric layer.

In an aspect which is particularly advantageous since it is expedient, a cleaning process is firstly performed prior to the application of the dielectric layer. In this cleaning process, the surface of the semiconductor body on which the dielectric layer is subsequently applied is firstly cleaned by means of a special cleaning sequence. The cleaning sequence comprises, inter alia, application of a specially selected cleaning liquid with the aid of which impurity particles on the surface of the substrate, which might have a harmful effect on the formation of a dielectric, are to be eliminated. This cleaning process serves the purpose of increasing the quality of the interface since the density of undesirable traps at the interface is reduced by a prior cleaning process. This makes it possible to prevent undesirable interface states caused by particles on the surface of the semiconductor body, for example. A dielectric, for example silicon dioxide or silicon nitride, is subsequently applied to the semiconductor surface using a customary method.

In addition or as an alternative, it may also be provided that a sacrificial oxide process is provided directly prior to the application of the dielectric layer to the semiconductor body. In this sacrificial oxide process, a thin layer of the semiconductor body is oxidized in order subsequently to be removed again. This sacrificial oxide process likewise serves the purpose of increasing the quality of the interface.

In an advantageous aspect, in addition to the fluorine-containing particles, carbon-containing and/or nitrogen-containing particles are also introduced into the semiconductor body or into the region of the interface.

In a likewise very advantageous embodiment, a forming gas annealing is performed after the application of the dielectric layer or at the end of the process flow, hydrogen-containing particles contained in the forming gas being introduced into the semiconductor body or into the region of the interface during the annealing. It has been shown that, in addition to the introduction of fluorine ions at the interface, the hydrogen contained in the forming gas entails an additional improvement of said interface and thus of the gate oxide.

In an advantageous aspect, the fluorine-containing particles are introduced into the semiconductor body at a dose of between 1*10¹³ cm⁻² and 1*10¹⁵ cm⁻². A particularly advantageous range for the dose introduced in the semiconductor body lies between 3*10¹³ cm⁻² and 3*10¹⁴ cm⁻². The use of a dose of more than 1*10¹⁵ cm⁻² in the case of silicon is not expedient since this exceeds the amorphization limit of the silicon semiconductor body, at which the semiconductor body loses its monocrystalline properties. This is undesirable and should therefore be avoided as far as possible.

In an advantageous aspect of the method according to the invention, a temperature in the range of between 400° C. and 1000° C. is set for the thermal annealing. Lower or else higher temperatures would also be conceivable, but the temperature range specified is particularly advantageously suitable in particular on account of the time for the thermal annealing and also for the electrical properties thereby obtained. Preferably, a thermal process is performed in the range of 800° C. to 1000° C. for a few, for example 10 seconds, as is customary in the case of an RTP process. It goes without saying that lower temperatures would also be conceivable but the time for the thermal process must then be increased.

In another advantageous aspect, it is possible to dispense with an annealing process or thermal process provided specifically for the saturation of the fluorine ions. This measure is based on the insight that even after the production of the dielectric layer, the semiconductor arrangement or the corresponding semiconductor component is still exposed to a multiplicity of different thermal processes. These thermal processes can virtually be concomitantly used for the diffusion of the fluorine ions and thus for the saturation. Thus, an annealing process or a thermal process is not dispensed with here, rather the function or the mode of operation of the annealing process or thermal process is replaced by the process steps—which likewise provide thermal processes—arranged downstream in the process flow for the fabrication of a respective semiconductor component. In this respect the thermal process steps that are effected later in the process flow designate the annealing process for the saturation of the traps. A dedicated process step can be dispensed with in this way.

In a particularly advantageous aspect, the process step for producing the dielectric layer may as it were form the annealing process or the thermal process for the saturation of the traps by the fluorine-containing particles. However, in this case the fluorine-containing particles must, of course, be introduced into the semiconductor body and thus into the region of the surface of the semiconductor body prior to the production of the dielectric layer. A further requirement is that the dielectric layer is formed as a thermal process, for example for producing a thermal silicon dioxide or a thermal silicon nitride. This thermal process for producing the dielectric layer thus equally forms the thermal process for the saturation of the fluorine-containing particles.

In another advantageous aspect, a short spike anneal step is carried out to thermally remove passivating atoms having a very small bond energy before the step of saturating the interface region. Often these passivating atoms are present at the interface region and are reducing the electrical properties of a semiconductor device if this device is not passivated and is exposed to high-electric fields. Preferably the short spike anneal step comprises a short heat treatment without a stop time at a temperature in the range of 800° C. to 1150° C. Also preferably the short spike anneal step comprises a short heat pulse having a pulse width in the range of 1 sec to 5 sec.

In still another advantageous aspect, the short spike anneal step is carried out prior to the deposition of a Si₃N₄ liner and/or at the end of a front-end-process and right before a subsequent mid-of-line process.

Typically but not necessarily, in case of applying the short spike anneal step the fluorine-containing particles are implanted in the interface region of the semiconductor body immediately after this short spike anneal step.

### BRIEF DESCRIPTION OF THE DRAWINGS

The invention is explained in more detail below on the basis of the exemplary embodiments specified in the schematic figures of the drawing, in which:

FIG. 1 shows a partial section through a semiconductor arrangement with an interface between dielectric layer and semiconductor body that is improved in accordance with the invention.

FIG. 2 shows schematic cross-sectional illustrations of successive method stages for fabricating an STI semiconductor arrangement according to the invention.

In all the figures of the drawing, unless specified otherwise, identical or functionally identical elements have been designated by the same reference symbols.

### DETAILED DESCRIPTION OF THE INVENTION

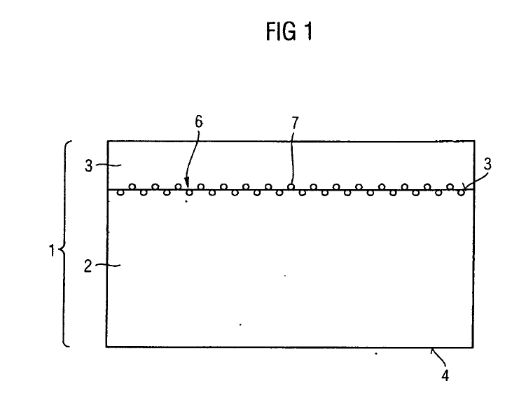

FIG. 1 shows a semiconductor arrangement fabricated in accordance with the invention on the basis of a schematic partial section.

In FIG. 1 the semiconductor arrangement according to the invention is designated by reference symbol 1. The semiconductor arrangement 1 comprises a semiconductor body 2, which includes a monocrystalline silicon substrate in the present exemplary embodiment. The semiconductor body 2 has a first surface 3 and a second surface 4, the first surface 3 forming the front side of the wafer and the second surface 4 forming the rear side of the wafer. A thin dielectric layer 5, which is formed as silicon dioxide in the present exemplary embodiment, is applied on the first surface 3. An interface 6 is thus formed between the semiconductor body 2 and the dielectric layer 5.

According to the invention, fluorine-containing particles, in particular fluorine ions 7 (F⁻), are then arranged in the region of said interface 6. In this case, the fluorine ions 7 may be provided in the region of the semiconductor body 2 or additionally or alternatively also in the region of the dielectric layer 5. FIG. 1 shows an exemplary illustration of a gate oxide interface to a silicon substrate.

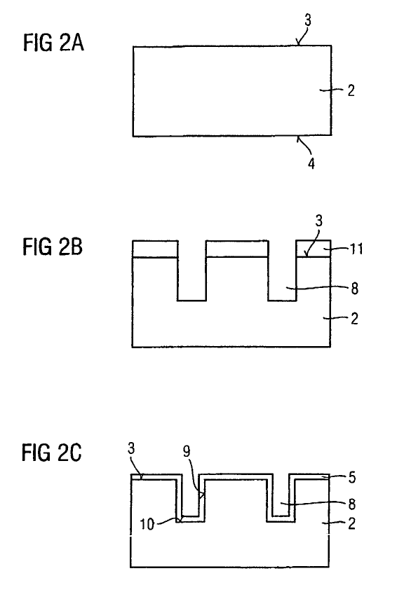

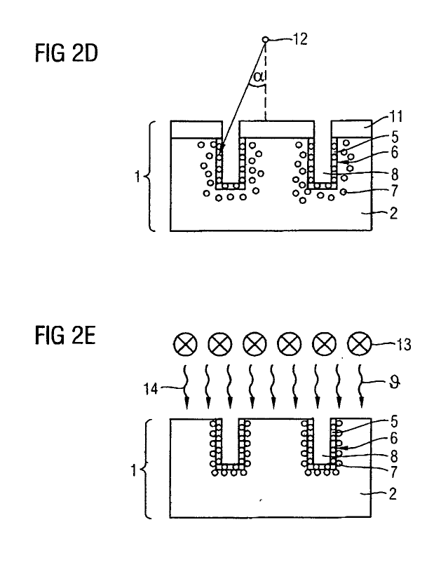

A method according to the invention for producing a semiconductor arrangement 1 is described below with reference to the partial sections specified in FIGS. 2(a) to 2(f). In this case, the method according to the invention will be described on the basis of a so-called STI semiconductor process. In this case, the numbering below corresponds to the corresponding subfigures of FIG. 2:

(a) a semiconductor body 2 having a first surface 3 and a second surface 4 is provided.

(b) In the region of the first surface 3, trenches 8 are introduced into the semiconductor body 2. The trenches 8 may be introduced into the semiconductor body 2 by anisotropic etching, for example, after a suitable patterning of the first surface 3 by means of a mask 11. The process steps and technological methods required for producing the trenches 8 are generally known, and so they need not be discussed in any greater detail.

Prior to the etching of the trenches 8 or additionally or alternatively also after the etching of the trenches 8, the semiconductor body 2 is subjected to a cleaning process in particular in the region of the first surface 3 and the trenches 8.

(c) A thermal oxidation is subsequently performed, during which a thin thermal oxide 5 is applied to the surface 3 of the semiconductor body 2. After the oxidation, a thin thermal oxide layer 5 has formed, on the side of the first surface 3, on all uncovered surfaces, that is to say on the trench walls 9 and the trench bottoms 10.

(d) The first surface 3 of the semiconductor body 2 is subsequently patterned again by means of the mask 11. The mask openings of the mask 11 are again situated in the region of the trenches 8. The same mask 11 as in method step (b) is advantageously used here.

Afterward, fluorine-containing particles 12 are implanted into the semiconductor arrangement 1 by means of shallow trench implantations. By way of example, BF₂ gas is used for the ion implantation, the fluorine ions 12 being extracted from the gas. During this shallow trench implantation, the fluorine ions 12 are implanted at a suitably chosen implantation energy and at a predetermined oblique implantation angle α (corresponds to the angle of incidence of the fluorine ions) relative to the first surface 3 of the semiconductor body 2. The implantation angle α is chosen such that the fluorine ions 12 can pass over the entire depth of the trenches 8 to the interface 6 between dielectric layer 5 and semiconductor body 2. Moreover, the implantation energy is set such that the fluorine ions 12, taking account of the oblique implantation angle α of the fluorine ions 12 and the resultant greater path distance of the fluorine ions 12 through the dielectric layer 5, are essentially arranged in the region of the interface 6 after the implantation. In particular, a very shallow implantation at relatively low implantation energies in the range of 10-40 keV is used here, thereby ensuring that the implanted fluorine ions 12 are arranged as near to the surface as possible at the interface 6 between semiconductor body 2 and dielectric layer 5.

It goes without saying that the angle α may also be 0°.

Preferably, a multiple implantation using different doping doses, implantation energies and implantation angles α may also be used here. Particularly in the case of very deep and/or very narrow trenches 8, it is occasionally necessary to vary the implantation energy and/or the implantation angles α.

Afterward, the mask 11 is removed from the first surface 3 prior to the subsequent thermal process.

(e) After the STI implantation, the semiconductor arrangement 1 is subjected to a thermal process. In this case, thermal radiation 14 that heats the semiconductor arrangement 1 is generated using an energy source 13, for example a plurality of halogen lamps. The temperature for heating the semiconductor arrangement 1 is set in a suitable manner by means of the thermal radiation 14 and the energy emitted by the energy source 13. What is achieved by means of this thermal process is that the fluorine ions 7 situated in the region of the interface 6 virtually move independently toward the interface 6. Ideally, almost all of the fluorine ions 7 are situated at the interface 6 between dielectric layer 5 and semiconductor body 2 after the thermal process 13.

A significant factor here is that the fluorine ions 7 have a very high diffusion constant and thus a very good diffusion property in the semiconductor substrate and in particular in a monocrystalline silicon substrate 2. This makes use of the effect that the fluorine ions 7 are oriented virtually independently in each case in the direction of the interface 6.

In the case of the STI semiconductor process outlined above with reference to FIGS. 2(a)-2(e), it must be taken into consideration that the process steps here have been described merely for better illustration of the invention and do not lay claim to completeness.

In a preferred but not necessary embodiment of the invention the fluorine-based passivation of the interface 6 has to be performed especially on those regions of the interface area 6 which are exposed to very high-electric electric fields. These high-electric fields, which can be in the range of greater 100 keV/cm may be a result of potential differences of about 1 V between a distance of less than 100 nm. The fundamental inventive step going along with the inventive method is to remove a layer of passivation atoms (being almost exclusive of hydrogen) by means of a very short heating pulse. The layer of passivating atoms are already present and having a very small bond energy. The short heating pulse may be a so-called spike anneal step, wherein this step may be a heat treatment of about 1000° C. without a stop time and having a pulse width of about 2 secs at a temperature of about 950° C. Subsequent to this short heat treatment for to remove the layer of passivating atoms preferably fluorine ions or fluorine-containing molecules are incorporated for example by ion implantation just above and under the interface area to be passivated. After this heat treatment another thermal step is performed. With this subsequent thermal step the fluorine particles being incorporated in the previous ion implantation step are enriched at the interface area. By this thermal step and by enrichment of the fluorine atoms these fluorine atoms are integrated within the semiconductor body at the interface area in a very stable state.

In addition to the aforementioned method being described with reference to FIGS. 2A to 2E these improvement is characterized by an additional step of thermally removing of passivating atoms having a very small bond energy (such as hydrogen atoms) by means of a very short heating impulse, such as spike anneal step.

In the following part, a preferred integration method is described to use the inventive method for example in a CMOS process for example to fabricate a conventional DRAM device.

A CMOS process flow is divided in general in three blocks. The first block is the so-called front-end of line (FEOL) or shortly front-end. The second block is a so-called mid-of-line (MOL). The last block is the so-called back-end-of line (BEOL) or shortly back-end. The process steps of the front-end block are all directly in contact with the semiconductor device (such as silicon). The middle block generates the first contacting level for direct wiring the semiconductor device with for example wolfram, titane, copper material. This midblock typically includes the direct contact electrodes, for example to contact the different contact areas of a transistor of the semiconductor device. The back-end steps includes wiring levels being arranged superior to the first wiring level of the mid-of-line and typically in addition to that the terminating passivation layer.

The mid-of-line process typically begins with a process step for depositing a diffusion barrier such as silicone nitride (Si₃N₄)—the so-called nitride liner—and a subsequent deposition of an oxide filling layer which is arranged typically between neigboring transistor contact areas (gate electrodes). According to the present invention prior to the deposition of the Si₃N₄ liner—that is at the end of the front-end-process—a very short spike anneal is performed to remove the passivating atoms having a small bond energy and to incorporate fluorine atoms by subsequent implanting fluorine ions in the semiconductor surface. This fluorine implant is being performed typically by an implanting dosis in the range between 7*10¹³ cm⁻² to 7*10¹⁴ cm⁻². The implantation is typically performed having a very flat implantation angle. The next thermal step in the normal process flow than can be automatically applied to generate the desired implanted fluorine atoms at the interface area.

Although the present invention has been described above on the basis of a preferred exemplary embodiment, it is not restricted thereto, but rather can be modified in diverse ways.

In particular, the selection of the layer materials is only by way of example and can be varied in many different ways. Moreover, the process steps described above can likewise be varied in manifold ways. Thus, instead of a thermal oxidation, it is also possible to provide a dry oxidation with O₂, a wet oxidation with H₂O, an oxidation with O₃ or a radical oxidation. In this case, however, it is necessary to choose a favorable temperature range in each case.

### List of Reference Symbols

1 Semiconductor arrangement
2 Semiconductor body
3 First surface, front side of wafer
4 Second surface, rear side of wafer
5 Dielectric layer, silicon dioxide
6 Interface
7 Fluorine-containing particles in the region of the interface, fluorine ions
8 Trenches
9 Trench walls
10 Trench bottoms
11 Mask
12 Implanted fluorine ions
13 Thermal energy source, halogen lamp
14 Thermal radiation
α Angle of implantation

1. A method for producing a dielectric on a semiconductor body, comprising:
providing a semiconductor body;
applying a dielectric layer on at least parts of a first surface of the semiconductor body so as to form at least partly an interface between the dielectric layer and the semiconductor body;
thermal annealing the semiconductor body and the dielectric layer; and
saturating an interface region between the semiconductor body and the dielectric layer by incorporation fluorine-containing particles temporally prior to the annealing at the interface region for improving the electrical properties.

2. The method according to claim 1, wherein the dielectric layer includes silicon dioxide and/or silicon nitride and/or high-K and/or low-K.

3. The method according to claim 1, wherein the dielectric layer is produced by thermal oxidation and/or by LP-CVD and/or by ALD-CVD.

4. The method according to claim 1, wherein the semiconductor body is formed as a silicon substrate.

5. The method according to claim 1, wherein the fluorine-containing particles are incorporated by implantation of fluorine ions or by implantation of ionized fluorine-containing molecules into the semiconductor body.

6. The method according to claim 5, wherein a multiple implantation is performed at different doses and/or different implantation energies and/or different angles of incidence of the implanted particles.

7. The method according to claim 1, wherein prior to the oxidation at the first surface, at least one trench is introduced into the semiconductor body and the dielectric layer is subsequently applied at least on parts of the surface of the trench or trenches.

8. The method according to claim 1, wherein the fluorine-containing particles are introduced into the semiconductor body by shallow trench implantation at an oblique angle of incidence of the implanted particles with respect to the first surface.

9. The method according to claim 1, wherein a process of cleaning the first surface is performed prior to the application of the dielectric layer.

10. The method according to claim 1, wherein prior to the application of the dielectric layer, a thin sacrificial oxide is applied on at least parts of the first surface, and is removed again prior to the application of the dielectric layer.

11. The method according to claim 1, wherein in addition to the fluorine containing particles, carbon containing and/or nitrogen containing particles are also introduced into the semiconductor body.

12. The method according to claim 2, wherein a forming gas annealing is performed after the application of the dielectric layer, hydrogen-containing particles being introduced into the semiconductor body during the annealing.

13. The method according to claim 1, wherein the fluorine-containing particles are introduced into the semiconductor body at a dose in the range of between 1013 cm-2 and 1015 cm-2.

14. The method according to claim 1, wherein the thermal annealing is carried out at a temperature in the range of between 400° C. and 1000° C.

15. The method according to claim 1, wherein the application of the dielectric layer is used for the thermal annealing.

16. The method according to claim 1, wherein a short spike anneal step is carried out to thermally remove passivating atoms having a small bond energy before saturating the interface region.

17. The method according to claim 16, wherein the short spike anneal comprises a short heat treatment without a stop time at a temperature in the range of 800° C. to 1150° C.

18. The method according to claim 16, wherein the short spike anneal comprises a short heat pulse having a pulse width in the range of 1 sec to 5 sec.

19. The method according to claim 16, wherein the short spike anneal is carried out prior to the deposition of a Si3N4 liner and/or at the end of a front-end-process.

20. The method according to claim 16, wherein immediately after the short spike anneal the fluorine-containing particles are implanted in the interface region of the semiconductor body.

21. A semiconductor arrangement comprising:
a semiconductor body;
a dielectric layer applied on a first surface of the semiconductor body; and
an interface arranged between the semiconductor body and the dielectric layer,
wherein fluorine-containing particles are arranged at the interface for improving the saturation and the electrical properties of the interface.

22. The semiconductor arrangement according to claim 21, wherein at the first surface at least one trench is introduced into the semiconductor body, and the dielectric layer is arranged at least on parts of the surface of the trench or trenches.

23. The semiconductor arrangement according to claim 21, wherein the dielectric layer is formed as a capacitor dielectric.
